(19) United States
(12) Patent Application Publication
(10) Pub. No.: US 2023/0326716 A1
(43) Pub. Date: Oct. 12, 2023

(54) PLASMA PROCESSING APPARATUS, PLASMA PROCESSING METHOD, AND DIELECTRIC WINDOW

(71) Applicant: Tokyo Electron Limited, Minato-ku, Tokyo (JP)

(72) Inventors: Eiki KAMATA, Nirasaki City, Yamanashi (JP); Hiroshi KANEKO, Nirasaki City, Yamanashi (JP); Taro IKEDA, Nirasaki City, Yamanashi (JP)

(21) Appl. No.: 18/042,513

(22) PCT Filed: Aug. 16, 2021
(86) PCT No.: PCT/JP2021/029880

§ 371 Date: Feb. 22, 2023

(30) Foreign Application Priority Data
Aug. 28, 2020 (JP) 2020-145021

(51) Int. Cl. H01J 37/32

(52) U.S. Cl. CPC H01J 37/32119; H01J 37/3222; H01J 37/32311; H01J 37/32201; H01J 37/3244

(57) ABSTRACT

A plasma processing apparatus includes a chamber having a processing space for performing plasma processing on a substrate and a synthesis space for synthesizing electromagnetic waves, a dielectric window configured to partition the processing space and the synthesis space, an antenna unit having a plurality of antennas that radiate the electromagnetic waves into the synthesis space and functioning as a phased array antenna, an electromagnetic wave output part configured to output the electromagnetic waves to the antenna unit, and a controller configured to cause the antenna unit to function as the phased array antenna. The dielectric window has a plurality of recesses on a surface thereof facing the processing space.

### TECHNICAL FIELD

The present disclosure relates to a plasma processing apparatus, a plasma processing method, and a dielectric window.

### BACKGROUND

A plasma processing apparatus is known in which a gas is turned into plasma by the power of electromagnetic waves to perform plasma processing on a substrate such as a semiconductor wafer or the like in a chamber. For example, Patent Document 1 describes a method of correcting the reaction rate on a semiconductor substrate in a processing chamber using a phased array microwave antenna in such a plasma processing apparatus. Specifically, a plasma is excited in a processing chamber, a microwave radiation beam is emitted from a phased array of microwave antennas, and the beam is directed into the plasma to change the reaction rate on the surface of a semiconductor substrate in the processing chamber.

### PRIOR ART DOCUMENT

### Patent Document

Patent Document 1: Japanese laid-open publication No. 2017-103454

The present disclosure provides some embodiments of a plasma processing apparatus, a plasma processing method, and a dielectric window, which are capable of generating localized plasma even in a high electron density region.

### SUMMARY

According to one embodiment of the present disclosure, there is provided a plasma processing apparatus, including: a chamber having a processing space for performing plasma processing on a substrate and a synthesis space for synthesizing electromagnetic waves; a dielectric window configured to partition the processing space and the synthesis space; an antenna unit having a plurality of antennas that radiate the electromagnetic waves into the synthesis space and functioning as a phased array antenna; an electromagnetic wave output part configured to output the electromagnetic waves to the antenna unit; and a controller configured to cause the antenna unit to function as the phased array antenna, wherein the dielectric window has a plurality of recesses on a surface thereof facing the processing space.

According to the present disclosure, it is possible to provide a plasma processing apparatus, a plasma processing method, and a dielectric window, which are capable of generating localized plasma even in a high electron density region.

### BRIEF DESCRIPTION OF DRAWINGS

FIG. 1 is a sectional view showing a plasma processing apparatus according to one embodiment.

FIG. 2 is a sectional view showing the details of an electromagnetic wave radiation part.

FIG. 3 is a diagram schematically showing the arrangement of antenna modules in the plasma processing apparatus of FIG. 1.

FIG. 4 is a block diagram showing the configuration of an electromagnetic wave output part in the plasma processing apparatus of FIG. 1.

FIG. 5 is a diagram for explaining the function of a recess of a dielectric window.

FIG. 6 is a diagram showing the relationship between the electromagnetic waves and the plasma in the case of low-density plasma.

FIG. 7 is a diagram showing the relationship between the electromagnetic waves and the plasma in the case of high-density plasma.

FIG. 8 is a diagram showing actual measurement data of the electron density in the z direction from the dielectric window.

FIG. 9 is a diagram schematically showing the relationship between the recess of the dielectric window and the plasma.

FIG. 10 is a bottom view showing the recess of the dielectric window.

FIGS. 11A to 11D are sectional views showing examples of the shape of the recess of the dielectric window.

FIG. 12 is a diagram showing an arrangement example of the recesses in the dielectric window.

FIG. 13 is a diagram showing another arrangement example of the recesses in the dielectric window.

FIG. 14 is a sectional view for explaining a processing state in the plasma processing apparatus according to one embodiment.

FIG. 15 is a schematic diagram for explaining the electromagnetic wave condensing principle in the plasma processing apparatus according to one embodiment.

FIG. 16 is a coordinate diagram representing the phase δ(x) at position O of the electromagnetic waves radiated from an electromagnetic wave radiation position x.

FIG. 17 is a schematic diagram showing the arrangement of each antenna and the phase at position O.

FIG. 18 is a schematic diagram showing a state in which the condensing portion of the dielectric window is scanned by phase control.

FIG. 19 is a sectional view showing another example of the gas introduction part.

### DETAILED DESCRIPTION

Embodiments of the present disclosure will now be described in detail with reference to the accompanying drawings.

### Plasma Processing Apparatus

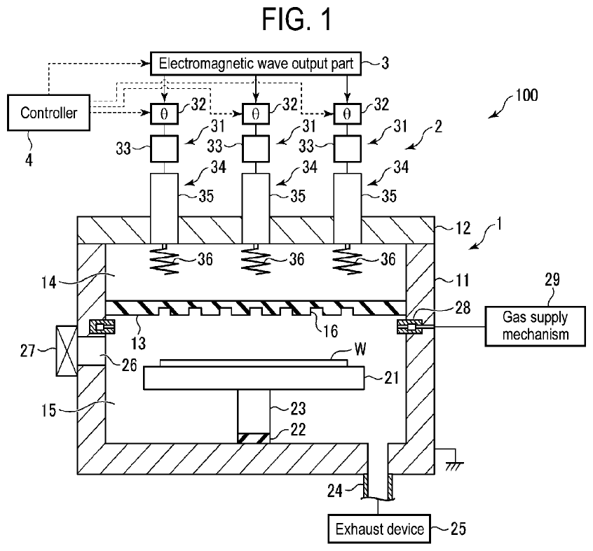

FIG. 1 is a sectional view showing a plasma processing apparatus according to one embodiment. The plasma processing apparatus 100 of the present embodiment is configured to generate surface wave plasma by electromagnetic waves (microwaves) and perform plasma processing such as film formation processing or etching processing on a substrate W by the plasma (mainly surface wave plasma) thus formed. A typical example of the substrate W is a semiconductor wafer. However, the substrate W is not limited thereto and may be other substrates such as an FPD substrate, a ceramics substrate, and the like.

The plasma processing apparatus 100 includes a chamber 1, an antenna unit 2, an electromagnetic wave output part 3, and a controller 4.

The chamber 1 has a substantially cylindrical shape and includes a container part 11 with an upper opening, and a top plate 12 that closes the upper opening of the container part 11. The chamber 1 is made of a metal material such as aluminum, stainless steel, or the like.

The space in the chamber 1 is vertically partitioned by a dielectric window 13. The space above the dielectric window 13 is a synthesis space 14 for synthesizing electromagnetic waves, and the space below the dielectric window 13 is a processing space 15 for performing plasma processing on the substrate W.

The synthesis space 14 is an atmospheric space. Electromagnetic waves are radiated into the synthesis space 14 from a plurality of antennas, which will be described later, of the antenna unit 2, and the radiated electromagnetic waves are synthesized.

The dielectric window 13 is made of a dielectric material, and has a plurality of recesses 16 formed on the surface thereof facing the processing space 15. The dielectric window 13 will be described later in detail.

In the processing space 15, a disk-shaped stage 21 on which the substrate W is horizontally mounted is provided, and surface wave plasma for processing the substrate W is formed. The processing space 15 is kept in a vacuum state during plasma processing.

The stage 21 is supported by a cylindrical support member 23 erected via an insulating member 22. Examples of the material of which the stage 21 is made include a metal such as aluminum whose surface is anodized, and a dielectric material such as ceramics. The stage 21 may be provided with an electrostatic chuck for electrostatically attracting the substrate W, a temperature control mechanism, a gas flow path for supplying a heat transfer gas to the rear surface of the substrate W, and the like.

Further, depending on the plasma processing, a radio-frequency bias power source may be electrically connected to the stage 21 via a matcher. Ions in the plasma are drawn toward the substrate W by supplying radio-frequency power from the radio-frequency bias power source to the stage 21.

An exhaust pipe 24 is connected to the bottom of the chamber 1, and an exhaust device 25 including a pressure control valve and a vacuum pump is connected to the exhaust pipe 24. When the exhaust device 25 is operated, the inside of the processing space 15 of the chamber 1 is evacuated and depressurized to a predetermined degree of vacuum. The side wall of the chamber 1 is provided with a loading/unloading port 26 for loading and unloading the substrate W, and a gate valve 27 for opening and closing the loading/unloading port 26.

At a position below the dielectric window 13 on the side wall of the chamber 1, a shower ring 28 having a ring-shaped gas flow path formed therein and a plurality of gas discharge holes opened inward from the gas flow path is provided as a gas introduction part. A gas supply mechanism 29 is connected to the shower ring 28. The gas supply mechanism 29 supplies a rare gas such as an Ar gas used as a plasma generation gas, and a processing gas used for plasma processing.

The antenna unit 2 radiates electromagnetic waves, which are outputted from the electromagnetic wave output part 3, from above the chamber 1 to the synthesis space 14 inside the chamber 1, and includes a plurality of antenna modules 31. The antenna module 31 includes a phase shifter 32, an amplifier part 33, and an electromagnetic wave radiation part 34. The electromagnetic wave radiation part 34 includes a transmission line 35 for transmitting the electromagnetic waves amplified by the amplifier part 33 and an antenna 36 extending from the transmission line 35 and configured to radiate electromagnetic waves to the synthesis space 14. The phase shifter 32 and the amplifier part 33 of the antenna module 31 are provided above the chamber 1. FIG. 1 shows an example in which a helical antenna is used as the antenna 36. The helical antenna is nothing more than an example, and the antenna 36 is not limited thereto. The helical antenna is preferable because it has high directivity in the axial direction and less mutual coupling between antennas.

The phase shifter 32 is configured to change the phase of electromagnetic waves and is configured to adjust the phase by advancing or delaying the phase of the electromagnetic waves radiated from the antenna 36. By adjusting the phase of the electromagnetic waves with the phase shifter 32, it is possible to utilize the interference of the electromagnetic waves radiated from the plurality of antennas 36 to concentrate the electromagnetic waves on the dielectric window 13 at a desired position.

The amplifier part 33 includes a variable gain amplifier, a main amplifier that constitutes a solid state amplifier, and an isolator. The variable gain amplifier is an amplifier for adjusting the power level of the electromagnetic waves inputted to the main amplifier, adjusting variations in the individual antenna modules 31, or adjusting the magnitude of the electromagnetic waves. The main amplifier may be configured to include, for example, an input matching circuit, a semiconductor amplifying element, an output matching circuit, and a high-Q resonance circuit. The isolator separates the reflected electromagnetic waves reflected by the antenna 36 and directed toward the main amplifier.

The transmission line 35 of the electromagnetic wave radiation part 34 is fitted into the top plate 12, and the lower end of the transmission line 35 is at the same height as the inner wall of the top plate 12. The antenna 36 extends from the lower end of transmission line 35 into the synthesis space 14 with its axis extending in the vertical direction. That is, the antenna 36 extends into the synthesis space 14 from the inner surface of the upper wall of the synthesis space 14. Copper, brass, silver-plated aluminum, or the like may be used as the antenna 36.

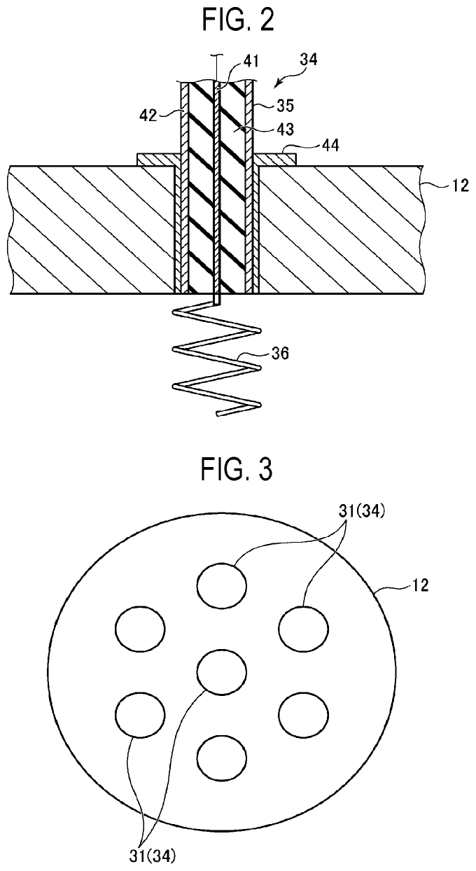

As shown in FIG. 2, the transmission line 35 includes an inner conductor 41 arranged at the center, an outer conductor 42 arranged around the inner conductor 41, and a dielectric member 43 made of Teflon (registered trademark) or the like and provided between the inner conductor 41 and the outer conductor 42. The transmission line 35 has the shape of a coaxial cable. Reference numeral 44 designates a sleeve. The antenna 36 is connected to the inner conductor 41.

The antenna modules 31 (electromagnetic wave radiation parts 34) are evenly provided on the top plate 12. The number of antenna modules 31 is set accordingly to form the appropriate plasma. In this example, as shown in FIG. 3, seven antenna modules 31 (electromagnetic wave radiation parts 34) are provided (only three of which are shown in FIG. 1).

By adjusting the phase of the electromagnetic waves radiated from the antenna 36 by the phase shifter 32 of each antenna module 31, it is possible to generate interference of the electromagnetic waves and concentrate the electromagnetic waves on an arbitrary portion of the dielectric window 13. That is, the antenna unit 2 functions as a phased array antenna.

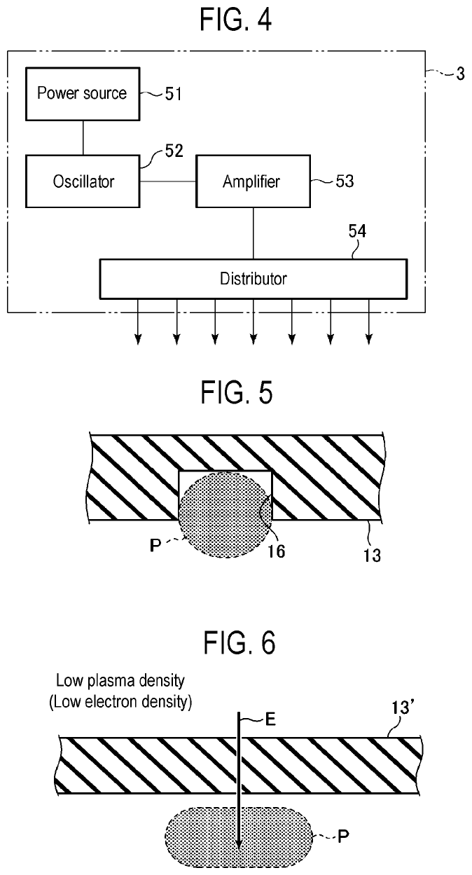

As shown in FIG. 4, the electromagnetic wave output part 3 includes a power source 51, an oscillator 52, an amplifier 53 for amplifying the oscillated electromagnetic waves, and a distributor 54 for distributing the amplified electromagnetic waves to the respective antenna modules 31, thereby outputting the electromagnetic waves to the respective antenna modules 31.

The oscillator 52 oscillates electromagnetic waves, for example, by PLL oscillation. As the electromagnetic waves, for example, electromagnetic waves having a frequency of 860 MHz is used. As the frequency of the electromagnetic waves, in addition to 860 MHz, frequencies in a microwave band in the range of 300 MHz to 3 GHz may be preferably used. The distributor 54 distributes the electromagnetic waves amplified by the amplifier 53.

The controller 4 has a CPU and controls each component of the plasma processing apparatus 100. The controller 4 includes a memory part that stores control parameters and processing recipes for the plasma processing apparatus 100, an input device, a display, and the like. The controller 4 controls the power of the electromagnetic wave output part 3, the gas supply from the gas supply mechanism 29, and the like. Further, the controller 4 outputs a control signal to the phase shifter 32 of each antenna module 31, controls the phase of the electromagnetic waves radiated from the electromagnetic wave radiation part 34 (antenna 36) of each antenna module 31, and performs control to generate interference of electromagnetic waves to concentrate the electromagnetic waves on a desired portion of the dielectric window 13. That is, the controller 4 controls the antenna unit 2 to function as a phased array antenna. In the following description, the act of concentrating electromagnetic waves on a desired portion by phase shift control is expressed as condensing.

The control of the phase shifter 32 by the controller 4 is performed, for example, by pre-storing in the memory part a plurality of tables which indicates the relationship between the phase of each antenna module and the condensing position of the electromagnetic waves, and switching the tables at a high speed.

The antenna unit 2, the electromagnetic wave output part 3, and the controller 4 constitute a plasma source that generates plasma for plasma processing.

### Dielectric Window

Next, the dielectric window 13 will be described. The dielectric window 13 has a function of transmitting the electromagnetic waves synthesized in the synthesis space 14. Examples of the dielectric material constituting the dielectric window 13 include quartz, ceramics such as alumina (Al₂O₃) or the like, a fluorine-based resin such as polytetrafluoroethylene or the like, and a polyimide-based resin.

As shown in FIG. 5, in the plurality of recesses 16 formed on the surface of the dielectric window 13 on the processing space 15 side, plasma P is generated by the electromagnetic waves transmitted through the dielectric window 13. That is, the recesses 16 have a function of confining the plasma P therein. More specifically, the electromagnetic waves synthesized in the synthesis space 14 and condensed at the desired position of the dielectric window 13 reach the processing space 15 through the dielectric window 13 and generate plasma P in the recesses 16. At this time, the recesses 16 confine the generated plasma P and prevents it from spreading in the in-plane direction.

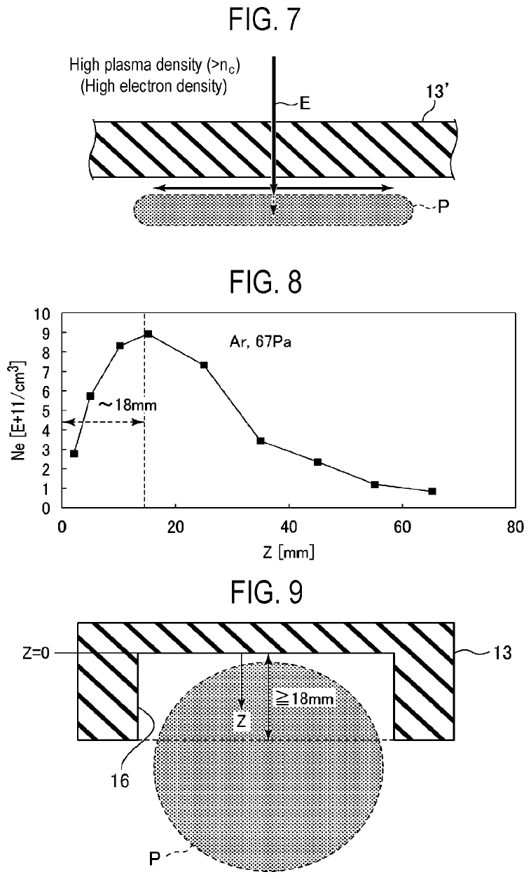

When an ordinary flat-plate dielectric window is used, if the generated plasma has a low plasma density (low electron density), as shown in FIG. 6, the electromagnetic waves E transmitted through the dielectric window 13′ penetrate into the plasma P in the processing space 15 to some extent, and do not spread so much in the in-plane direction. However, if the plasma density rises to a high plasma density (high electron density) exceeding the frequency-dependent cutoff density n_{c} expressed by the following equation, as shown in FIG. 7, the electromagnetic waves E penetrating into the plasma P is attenuated, and the spreading of the electromagnetic waves in the plane direction is increased. If the spreading of the plasma in the plane direction becomes large in this way, it is difficult to generate localized plasma, which is the purpose of the phased array antenna.

$${n}_{c} = \frac{{m}_{e} {ϵ}_{0} {ω}^{2}}{{e}^{2}} \qquad [ Equation 1 ]$$

$$ω = 2 π f ,$$

where mₑ is an electron mass (=9.1093×10⁻³¹ kg), ϵ₀ is a vacuum dielectric constant (=8.8542×10⁻¹² F/m), e is an elementary electric charge of electron (=1.6022×10⁻¹⁹ C), ω is an electromagnetic wave angular frequency [rad/s], and f is an electromagnetic wave frequency [/s]. For example, if the frequency of electromagnetic waves is 860 MHz, n_{c} is 9.1743×10⁹ [cm⁻³].

Therefore, in the present embodiment, the recesses 16 are provided on the surface of the dielectric window 13 on the side of the processing space 15, and plasma is generated in the recesses 16. The plasma is confined in the recesses 16 to suppress the spreading of the plasma in the plane direction. Although the effect of the recesses 16 is exhibited even in low-density plasma, it is particularly effective in generating high-density plasma in which the plasma density exceeds the cutoff density n_{c}.

The depth of the recesses 16 is preferably set to a depth that can confine the plasma. The measured data of the electron density at 67 Pa in Ar gas plasma are shown in FIG. 8. The electron density has a maximum value at 18 mm from the dielectric window. Therefore, as shown in FIG. 9, the plasma is confined in the recesses when the depth of the recesses 16 is 18 mm or more. Accordingly, it is preferable that the depth of the recesses is 18 mm or more.

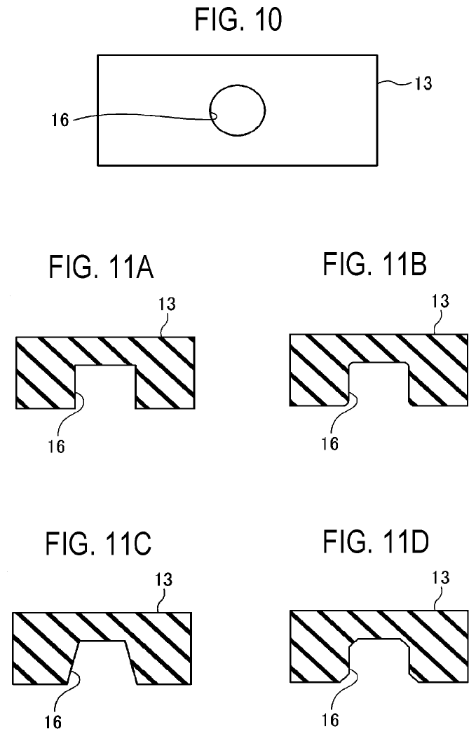

The size of the recesses 16 is not particularly limited, and may be appropriately set according to the required size of plasma. Further, the shape of the recesses 16 is not particularly limited. It is preferable that the recesses 16 has a circular plan-view shape as shown in FIG. 10 which is a bottom view. Further, the vertical sectional shape of the recesses 16 may be a straight shape (cylindrical shape) as shown in FIG. 11A. Moreover, as shown in FIG. 11B, the frontage on the side of the processing space 15 may have a wide cone shape. Since the cone shape has an angle wider than 90°, the discharge is stable. From the viewpoint of stabilizing the discharge, the shape may be a rounded corner shape as shown in FIG. 11C or a chamfered shape as shown in FIG. 11D.

Further, the number and pitch of the recesses 16 are not particularly limited, and may be appropriately set so that a uniform plasma is generated over the entire surface of the substrate W while generating target local plasma. For example, the pitch, which is the distance between the centers of the recesses 16, is preferably 56 mm or less, and the number of recesses 16 is preferably 37 or more when the substrate W is a 300 mm wafer. It is preferable that the recesses 16 are uniformly provided in the area where the substrate W is arranged. In particular, when the area where the substrate W is arranged is divided into a plurality of areas according to the plasma generating areas, it is preferable that the number of recesses 16 be the same in each section. In addition, it is preferable that the area of the dielectric window 13 where the recesses 16 are formed is wider than the area where the substrate W is arranged.

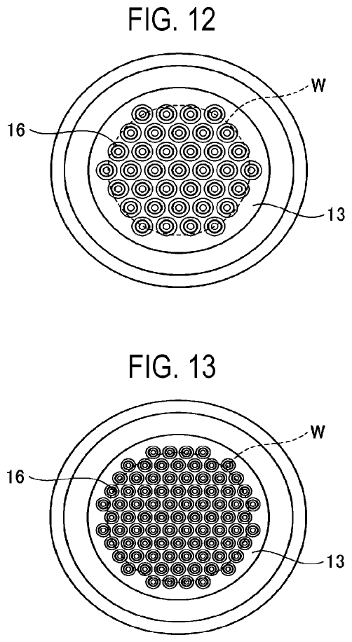

FIGS. 12 and 13 show examples of arrangement of the recesses 16 in the dielectric window 13. These figures show the case where the substrate W corresponds to a 300 mm wafer. FIG. 12 shows an example in which the number of recesses 16 is 37, the pitch of the recesses is 56 mm, the recesses 16 are cone-shaped, and the diameter of the frontage of the recesses 16 is 36 mm. FIG. 13 shows an example in which the number of recesses 16 is 87, the pitch of the recesses is 40 mm, the recesses 16 are cone-shaped, and the diameter of the frontage of the recesses 16 is 24 mm. In the example of FIG. 12, for example, when one section is a hexagon having a side of 56 mm, the number of recesses 16 is seven in all sections, which can be made uniform. Further, in the example of FIG. 13, for example, when one section is a hexagon having a side of 40 mm, the number of recesses 16 is seven in all sections, and the number of recesses can be made uniform. Broken lines in FIGS. 12 and 13 indicate the position of the substrate W.

In the present embodiment, the interference of electromagnetic waves is used to move the condensing portions of the electromagnetic waves to generate plasma in the recesses 16 corresponding to the condensing portions. The plasma corresponding to the condensing portion at a given time may be generated not only in one recess 16 but also in the surrounding recesses 16. In this case, the plasma intensity in the central recess 16 is high, and the plasma intensity in the surrounding recesses 16 is low.

### Plasma Processing Method

Next, a plasma processing method using the plasma processing apparatus 100 configured as above will be described. The following operations are performed under the control of the controller 4.

First, the gate valve 27 is opened, and the substrate W is transferred from a vacuum transfer chamber (not shown) adjacent to the chamber 1 into the processing space 15 of the evacuated chamber 1 through the loading/unloading port 26 by a transfer device (not shown), and is placed on the stage 21.

After the gate valve 27 is closed, the pressure in the processing space 15 is adjusted to a predetermined vacuum pressure by the exhaust device 25, and the electromagnetic waves are outputted from the electromagnetic wave output part 3 while introducing a gas for plasma processing into the processing space 15 from the gas introduction mechanism 29. The electromagnetic waves outputted from the electromagnetic wave output part 3 are supplied to the antenna modules 31 of the antenna unit 2 and radiated from the electromagnetic wave radiation parts 34 of the antenna modules 31 to the synthesis space 14 of the chamber 1.

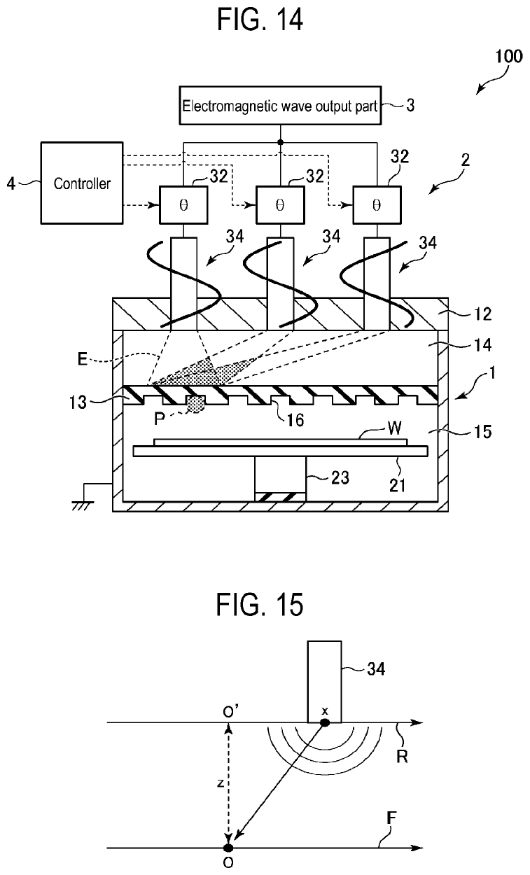

At this time, as shown in FIG. 14, the phase of the electromagnetic waves E radiated from the electromagnetic wave radiation part 34 (antenna 36) of each antenna module 31 is controlled by outputting a control signal from the controller 4 to the phase shifter 32. That is, the antenna unit 2 is caused to function as a phased array antenna. As a result, the interference of the electromagnetic waves is generated in the synthesis space 14 to form a condensing portion of the electromagnetic waves E, i.e., a portion having a high electromagnetic wave intensity in a desired portion of the dielectric window 13, and the condensing portion of the electromagnetic waves can be moved at a high speed by controlling the phase of the electromagnetic waves E radiated from the electromagnetic wave radiation part 34. By controlling the electromagnetic wave distribution per unit time and per unit area in this way, it is possible to eliminate the uneven electromagnetic wave distribution that is dependent on the physical arrangement of the electromagnetic wave radiation parts 34 when the electromagnetic waves are radiated from the electromagnetic wave radiation parts 34. As a result, a uniform electromagnetic wave distribution can be obtained.

The electromagnetic waves condensed on the dielectric window 13 pass through the dielectric window 13 and generate localized plasma in the processing space 15 at a position just below the condensing portion by the electric field thereof. Further, uniform plasma generation as a whole is expected due to the high-speed movement of the localized plasma accompanying the high-speed movement of the electromagnetic wave condensing portion.

Focusing on one position of the dielectric window 13, the high-speed phase control provides a timing at which the electric field concentrates and a timing at which there is no electric field. As a result, it is expected to generate pseudo-pulse plasma with less damage than normal microwave plasma.

The electromagnetic waves passing through the dielectric window 13 spread as surface waves in the in-plane direction immediately below the dielectric window 13, thereby generating surface wave plasma in the processing space 15. At this time, if the plasma density is low, as shown in FIG. 6, the electromagnetic waves E penetrate into the plasma P to some extent. Therefore, the in-plane spread of the plasma is not so large. However, when the plasma density reaches a high plasma density (high electron density) exceeding the cutoff density n_{c}, as shown in FIG. 7, the electromagnetic waves penetrating into the plasma are attenuated, and the spreading of the electromagnetic waves in the plan direction is increased. When the plasma spreads widely in the plane direction in this way, it becomes difficult to generate localized plasma, which is the purpose of the phased array antenna. In addition, it is difficult for the high-speed phase control to generate uniform plasma in the entire processing space and to generate low-damage pseudo-pulse plasma.

Therefore, in the present embodiment, as shown in FIG. 14, the recesses 16 are provided on the surface of the dielectric window 13 on the processing space 15 side so that the plasma P is generated therein, thereby suppressing the spreading of the plasma P in the plane direction. As a result, even at a high plasma density equal to or higher than the cutoff density n_{c}, localized plasma, which is the purpose of the phased array antenna, can be generated, and the localized plasma can be moved at a high speed by high-speed phase control to generate uniform plasma throughout the processing space 15. In addition, since the localized plasma can be generated in this way, even at a high plasma density equal to or higher than the cutoff density n_{c}, it is possible to realize pseudo-pulse plasma expected by high-speed phase control and to achieve a desired low damage process.

Next, the electromagnetic wave phase control in the antenna unit 2 will be specifically described with reference to FIGS. 15 to 17.

FIG. 15 is a schematic diagram for explaining the condensing principle in the plasma processing apparatus 100 according to one embodiment. The back surface of the top plate 12 on which the position of electromagnetic wave radiation from the electromagnetic wave radiation part 34 exists is defined as a radiation surface R, the surface of the dielectric window 13 irradiated with the electromagnetic waves is defined as an irradiation surface F, and the distance between the radiation surface R and the irradiation surface F is defined as z. The position on the irradiation surface F at which the electromagnetic waves are to be condensed is defined as O, and the position on the radiation surface R corresponding to the position O is defined as O′. At this time, the phase of the electromagnetic waves radiated from the electromagnetic wave radiation part 34 which is spaced apart by x from the position O′ is considered. The distance between the condensing position O and the position O′ is z, and the distance between the position O and the electromagnetic wave radiation position x of the electromagnetic wave radiation part 34 is (x²+z²)^{1/2}. If the wavenumber of the electromagnetic waves is defined as k (=2π/λ where λ is the wavelength of the electromagnetic waves), and the phase at the position O of the electromagnetic waves radiated from the position x (i.e., the phase difference between the phase at the position O of the electromagnetic waves radiated from the position x and the phase at the position O of the electromagnetic waves radiated from the position O′) is defined as δ(x), the following equation (1) holds.

k(x²+z²)^{1/2}−δ(x)=kz (1)

By modifying the equation (1), the following equation (2) for obtaining the phase δ(x) is obtained.

δ(x)=k{(x²+z²)^{1/2}−z} (2)

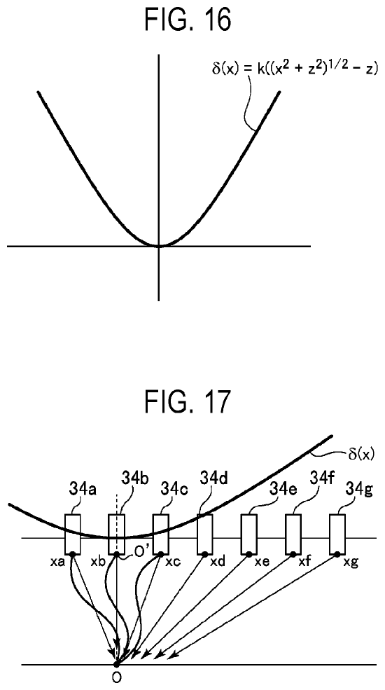

The curve shown in FIG. 16 is obtained by expressing the phase δ(x) on coordinates as a function of x.

The phase δ(x) can be grasped as a deviation in a traveling direction between the electromagnetic waves moving from the position O′ to the position O and the electromagnetic waves moving from the position x to the position O. The phase δ(x) increases as the electromagnetic wave radiation position of the electromagnetic wave radiation part 34 moves away from the position O′ (i.e., as the absolute value of x increases). Therefore, by advancing or delaying the phase θ of the electromagnetic waves radiated from the electromagnetic wave radiation part 34 in accordance with the value of the phase δ(x), the electromagnetic waves radiated from the plurality of electromagnetic wave radiation parts 34 can be intensified at the position O.

For example, a case is considered where, as shown in FIG. 17, there are seven electromagnetic wave radiation parts 34a, 34b, 34c, 34d, 34e, 34f and 34g, the electromagnetic wave radiation position of the electromagnetic wave radiation part 34b is the position O′, and other electromagnetic wave radiation parts are located away from the position O′. For the sake of convenience of description, FIG. 17 shows a state in which the electromagnetic wave radiation parts are arranged side by side unlike their actual positions.

The x-direction electromagnetic wave radiation positions of the electromagnetic wave radiation parts 34a to 34g are xa to xg. Since the distances between these positions xa to xg and the condensing position O are different, if electromagnetic waves are radiated with the same phase, a phase deviation occurs at the position O, and interference of the electromagnetic waves does not occur, which makes it impossible to increase the intensity of the electromagnetic waves. Therefore, the phase θ of the electromagnetic waves radiated from each electromagnetic wave radiation part 34 is shifted by a phase (phase difference) δ(x) corresponding to the x-direction positions of the electromagnetic wave radiation parts 34a to 34g so that the phases at the position O of the electromagnetic waves radiated from the respective electromagnetic wave radiation parts are matched. As a result, the interference of electromagnetic waves occurs at the position O, the electromagnetic waves are intensified, the electromagnetic waves are condensed at the position O, and the electric field intensity can be locally increased. FIG. 17 shows a state in which the phases of the electromagnetic waves radiated from the electromagnetic wave radiation parts 34a, 34b and 34c are matched at the position O to provide a condition that the electromagnetic waves are intensified by interference.

However, the phase control for intensifying the electromagnetic waves at the condensing position O does not need to be performed in all the electromagnetic wave radiation parts 34a to 34g as long as the desired electric field intensity is obtained by the interference of the electromagnetic waves at the position O, and may be performed in an appropriate number of, e.g., two or more, electromagnetic wave radiation parts. Further, in the above description, the number of condensing positions in the dielectric window 13 is one. However, the present disclosure is not limited thereto. Control that intensifies the phase at two or more positions in the dielectric window 13 at the same timing may be performed.

The distance from the center of the electromagnetic wave radiation part 34 to the center of the adjacent electromagnetic wave radiation part 34 is preferably smaller than λ/2, where λ is the wavelength of the electromagnetic waves. This is because if the distance (interval) between the adjacent electromagnetic wave radiation parts 34 is larger than λ/2, it becomes difficult to perform control for intensifying the phases of the electromagnetic waves at the condensing position O of the dielectric window 13.

Since the above-described condensing of the electromagnetic waves utilizes the interference of the electromagnetic waves generated by phase control, the condensing portion can be moved at a very high speed only by the phase control without any mechanical operation. In principle, the condensing portion can be moved at a speed in a same degree with the frequency of the electromagnetic waves.

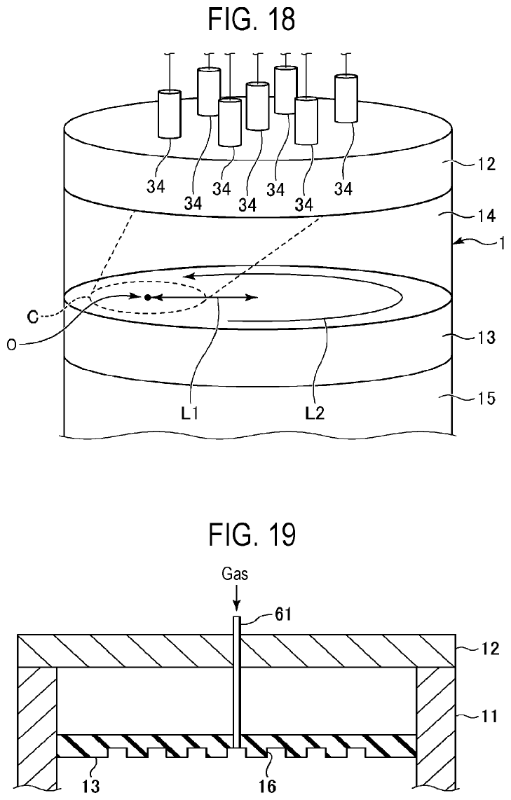

FIG. 18 is a diagram showing an example of the condensing of the electromagnetic waves by the phase control and the scanning of the condensing portion. In the example of FIG. 18, the controller 4 controls the phase shifter 32 (not shown in FIG. 18) to intensify the phases of the electromagnetic waves radiated from the seven electromagnetic wave radiation parts 34 at the position O. As a result, a condensing portion C is formed in a region centered on the position O, and the electric field of the electromagnetic waves is controlled to be intensive in the condensing portion C. This is schematically shown in FIG. 18. Then, by the phase control using the phase shifter 32, the phases of the electromagnetic waves radiated from the seven electromagnetic wave radiation parts 34 are controlled at a high speed so that the condensing portion C is scanned on the surface of the dielectric window 13 in the radial direction L1, the circumferential direction L2, or the like.

In addition, the controller 4 controls the phase shifter 32 to change the moving speed of the condensing portion C by controlling the phase of the electromagnetic waves radiated from the electromagnetic wave radiation part 34, whereby it is possible to freely control the average electric field distribution per unit time. For example, the phase of the electromagnetic waves is controlled so that the condensing portion C moves relatively slowly on the outer peripheral side of the dielectric window 13 and moves relatively fast on the inner peripheral side thereof. As a result, the electric field intensity on the outer peripheral side of the dielectric window 13 can be made stronger than the electric field intensity on the inner peripheral side, and the plasma density on the outer peripheral side of the dielectric window 13 can be controlled to be higher than the plasma density on the inner peripheral side.

In the present embodiment, in addition to obtaining high controllability of the condensing portion C by such high-speed phase control of electromagnetic waves, the plurality of recesses 16 is provided on the dielectric window 13 on the side of the processing space 15. As a result, even when the plasma density is higher than the cutoff density n_{c} and the plasma is easy to spread in the in-plane direction, the spread in the in-plane direction can be suppressed in the recesses 16 corresponding to the condensing portion C of the electromagnetic waves, and the localized plasma can be generated. As the electromagnetic wave condensing portion C moves at a high speed, the plasma generated in one recess 16 can also move to another recess 16 at a high speed, which makes it possible to perform uniform plasma processing.

In addition, since the localized plasma can be generated in this way, it is possible to realize pseudo-pulse plasma expected by high-speed phase control even at a high plasma density and to achieve a process with even less damage than ordinary microwave plasma.

By the way, in the ordinary microwave plasma, a standing wave with many short nodes and antinodes is formed directly under the dielectric window. Therefore, it is necessary to diffuse the electromagnetic waves (diffuse the plasma) in order to obtain uniformity of the plasma, and it is necessary to enlarge the gap between the dielectric window and the substrate. On the other hand, in the present embodiment, the plasma uniformity is high and the process can be performed with extremely low damage. Accordingly, plasma uniformity and low damage can be maintained even if the gap between the dielectric window 13 and the substrate is narrowed.

Therefore, the plasma processing apparatus of the present embodiment is suitable for an ALD process in which at least a first gas and a second gas are sequentially supplied to a substrate to form a film. That is, the plasma processing apparatus of the present embodiment can achieve both a narrow gap for short-time purging and a film-forming process with low damage to a substrate by microwave plasma and good film-forming characteristics, which are required in an ALD process.

When applied to the ALD process, uniformity of a gas flow is required. Therefore, as shown in FIG. 19, it is preferable to introduce a gas through a gas introduction part 61 that supplies the gas from near the center of the dielectric window 13.

### Other Applications

Although the embodiments have been described above, the embodiments disclosed herein should be considered to be exemplary and not limitative in all respects. The above-described embodiments may be omitted, substituted, or modified in various ways without departing from the scope and spirit of the appended claims.

For example, the configuration of the antenna module is not limited to that of the above embodiments. For example, the phase shifter may be provided closer to the antenna than the amplifier part, or the phase shifter may be provided integrally with the amplifier part. Further, the configuration of the electromagnetic wave output part is not limited to the above embodiments. In addition, the shape, size, number, etc. of the recesses can also be appropriately determined according to the processing.

### EXPLANATION OF REFERENCE NUMERALS

1: chamber, 2: antenna unit, 3: electromagnetic wave output part, 4: controller, 13: dielectric window, 14: synthesis space, 15: processing space, 16: recess, 21: stage, 31: antenna module, 32: phase shifter, 34: electromagnetic wave radiation part, 36: antenna, 100: plasma processing apparatus, W: substrate

1. A plasma processing apparatus, comprising:
a chamber having a processing space for performing plasma processing on a substrate and a synthesis space for synthesizing electromagnetic waves;
a dielectric window configured to partition the processing space and the synthesis space;
an antenna unit having a plurality of antennas that radiate the electromagnetic waves into the synthesis space and functioning as a phased array antenna;
an electromagnetic wave output part configured to output the electromagnetic waves to the antenna unit; and
a controller configured to cause the antenna unit to function as the phased array antenna,
wherein the dielectric window has a plurality of recesses on a surface thereof facing the processing space.

2. The apparatus of claim 1, wherein plasma is generated in the recesses.

3. The apparatus of claim 1, wherein a depth of the recesses is 18 mm or more.

4. The apparatus of claim 1, wherein the recesses have a cone shape with a wide frontage on the side of the processing space.

5. The apparatus of claim 1, wherein the recesses have a shape with rounded corners or a chamfered shape.

6. The apparatus of claim 1, wherein a pitch between the recesses is 56 mm or less.

7. The apparatus of claim 1, wherein the number of the recesses is 37 or more when the substrate is a wafer with a diameter of 300 mm.

8. The apparatus of claim 1, wherein an area of the dielectric window where the recesses are formed is wider than an area corresponding to the substrate.

9. The apparatus of claim 1, wherein the controller is configured to control a phase of each of the electromagnetic waves radiated from the plurality of antennas so that a condensing portion where the electromagnetic waves are condensed at an arbitrary position on the surface of the dielectric window due to interference when synthesizing the electromagnetic waves in the synthesis space is formed and moved.

10. The apparatus of claim 9, wherein the controller is configured to control an average electric field distribution per unit time by changing a moving speed of the condensing portion by phase control.

11. The apparatus of claim 1, wherein a density of the plasma generated in the processing space is higher than a cutoff density above which the electromagnetic waves penetrating into the plasma are attenuated.

12. The apparatus of claim 1, further comprising:
a gas supply part configured to supply at least a first gas and a second gas to the processing space,
wherein at least the first gas and the second gas are sequentially supplied to the substrate to form a film by ALD.

13. A substrate processing method for subjecting a substrate to plasma processing by a plasma processing apparatus that includes a chamber having a processing space for performing plasma processing on the substrate and a synthesis space for synthesizing electromagnetic waves, a dielectric window configured to partition the processing space and the synthesis space, an antenna unit having a plurality of antennas configured to radiate electromagnetic waves into the synthesis space, and an electromagnetic wave output part configured to output the electromagnetic waves to the antenna unit, the dielectric window having a plurality of recesses on a surface thereof facing the processing space, the substrate processing method comprising:
arranging the substrate in the processing space;
controlling a phase of each of the electromagnetic waves radiated from the antennas so that the antenna unit functions as a phased array antenna;
controlling the phases of the electromagnetic waves to form and move a condensing portion where the electromagnetic waves are condensed at an arbitrary position on the surface of the dielectric window; and
generating plasma in the recesses of the dielectric window by the electromagnetic waves transmitted through the dielectric window from the condensing portion to process the substrate with the plasma.

14. The method of claim 13, wherein an average electric field distribution per unit time is controlled by changing a moving speed of the condensing portion by the phase control.

15. A dielectric window through which electromagnetic waves radiated from a plurality of antennas of an antenna unit functioning as a phased array antenna into a synthesis space for synthesizing the electromagnetic waves are transmitted into a processing space where a substrate is arranged, the dielectric window comprising:
a plurality of recesses on a surface thereof facing the processing space.

16. The dielectric window of claim 15, wherein plasma is generated in the recesses.

17. The dielectric window of claim 15, wherein a depth of the recesses is 18 mm or more.

18. The dielectric window of claim 15, wherein a pitch between the recesses is 56 mm or less.

19. The dielectric window of claim 15, wherein the number of the recesses is 37 or more when the substrate is a wafer with a diameter of 300 mm.

20. The dielectric window of claim 15, wherein an area of the dielectric window where the recesses are formed is wider than an area corresponding to the substrate.
